(19) United States
(12) Patent Application Publication
(10) Pub. No.: US 2011/0001527 A1
(43) Pub. Date: Jan. 6, 2011

(54) DUTY-CYCLE ERROR CORRECTION CIRCUIT

(76) Inventor: Kyung-su Lee, Yongin-si (KR)

Correspondence Address: Muir Patent Consulting, PLLC, 9913 Georgetown Pike, Suite 200, P.O. Box 1213, Great Falls, VA, 22066, US

(21) Appl. No.: 12/828,390

(22) Filed: Jul. 1, 2010

(30) Foreign Application Priority Data
Jul. 3, 2009 (KR) 10-2009-0060832

(51) Int. Cl. H03L 7/06

(52) U.S. Cl. 327/158

(57) ABSTRACT

A duty cycle error correction circuit is disclosed. The circuit includes an inversion and delay circuit and a phase interpolator. The inversion and delay circuit is configured to receive an input signal having a waveform that includes a duty cycle error, delay and invert the input signal to form an inverted delayed signal, a determine whether the input signal and the inverted delayed signal are in phase. The phase interpolator is configured to receive the input signal, receive the inverted delayed signal, interpolate the received input signal and the received inverted delayed signal, and based on the interpolation, output a duty cycle error corrected signal.

### CROSS-REFERENCE TO RELATED APPLICATIONS

This application claims the benefit of Korean Patent Application No. 10-2009-0060832, filed on Jul. 3, 2009, in the Korean Intellectual Property Office, the disclosure of which is incorporated herein in its entirety by reference.

### BACKGROUND

The disclosed embodiments relate to a circuit for correcting a duty cycle error, and particularly, to a duty cycle error correcting circuit comprising a phase interpolator.

Recently, as interfaces between semiconductor chips are required to perform at higher transmission speeds, concerns with parameters such as jitter and duty cycle error of an external reference clock have become more prevalent. While certain circuits, such as static duty cycle error correction circuits, have been developed to reduce duty cycle error in semiconductor chips, these circuits can consume a lot of power and have other associated drawbacks. Accordingly, a new way of correcting duty cycle errors is desirable.

### SUMMARY

In one embodiment, a duty cycle error correction circuit is disclosed. The circuit includes an inversion and delay circuit and a phase interpolator. The inversion and delay circuit is configured to receive an input signal having a waveform that includes a duty cycle error, delay and invert the input signal to form an inverted delayed signal, a determine whether the input signal and the inverted delayed signal are in phase. The phase interpolator is configured to receive the input signal, receive the inverted delayed signal, interpolate the received input signal and the received inverted delayed signal, and based on the interpolation, output a duty cycle error corrected signal.

In another embodiment, another duty-cycle error correction circuit is disclosed. The circuit includes a first phase interpolator generating a first duty-cycle error corrected signal by interpolating an external input signal and an inverted delayed signal. The circuit additionally includes an inversion and delay circuit generating the inverted delayed signal by delaying and inverting the external input signal. When the inverted delayed signal and the external input signal are determined to be in phase, the inversion and delay circuit transmits the inverted delayed signal to the first phase interpolator. The circuit further includes a second phase interpolator generating a second duty-cycle error corrected signal by interpolating the external input signal and the first duty-cycle error corrected signal.

In another embodiment, a method of correcting a duty-cycle error in a clock signal is disclosed. The method includes (a) inverting and delaying an external input signal received from an external clock, thereby creating an inverted delayed signal, and (b) determining whether the inverted delayed signal is in phase with the external input signal. The method further includes (c) if the inverted delayed signal is not in phase with the external input signal, then repeating steps (a) and (b) with a successively increased amount of delay until it is determined that the inverted delayed signal is in phase with the external input signal. The method also includes (d) after it is determined that the inverted delayed signal is in phase with the external input signal, inputting the inverted delayed signal into an interpolator, and (e) interpolating by the interpolator the inverted delayed signal and the external input signal, and outputting a first output signal that has a reduced duty-cycle error compared to the external input signal.

### BRIEF DESCRIPTION OF THE DRAWINGS

Exemplary embodiments will be more clearly understood from the following detailed description taken in conjunction with the accompanying drawings in which:

FIG. 1 is a circuit diagram of an exemplary duty-cycle error correction circuit according to one embodiment;

FIG. 1a is a circuit diagram of an exemplary interpolator according to one embodiment;

FIG. 1b is a circuit diagram of an exemplary inverter that is part of the interpolator of FIG. 1a, according to one embodiment;

FIG. 2a is an exemplary operational timing diagram of the duty-cycle error correction circuit of FIG. 1;

FIG. 2b is another exemplary operational timing diagram of the duty-cycle error correction circuit of FIG. 1;

FIG. 3 is a circuit diagram of an exemplary duty-cycle error correction circuit according to another embodiment;

FIG. 4 is a circuit diagram of an exemplary duty-cycle error correction circuit according to another embodiment;

FIG. 5 is an exemplary operational timing diagram of the duty-cycle error correction circuit of FIG. 4;

FIG. 6 is a circuit diagram of an exemplary duty-cycle error correction circuit according to another embodiment; and

FIG. 7 is an exemplary operational timing diagram of the duty-cycle error correction circuit of FIG. 6.

It should be noted that these figures are intended to illustrate the general characteristics of methods, structure, and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative size and positioning components and/or structural elements may be reduced or exaggerated for clarity. The use of similar or identical reference numbers in the various drawings is intended to indicate the presence of a similar or identical element or feature.

### DETAILED DESCRIPTION OF THE EMBODIMENTS

Example embodiments will now be described more fully with reference to the accompanying drawings. Example embodiments may, however, be embodied in many different forms and should not be construed as being limited to the embodiments set forth herein. Rather, these embodiments are provided so that this disclosure will be thorough and complete, and will fully convey the concept of example embodiments to those of ordinary skill in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, unless noted otherwise, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In general, in the field of digital clock applications such as semiconductor integrated circuits, clock signals having a duty-cycle of 50% are mainly used. A duty-cycle of 50% means that the length of a high level part and a low level part of a clock signal during one clock cycle are equal to each other. In situations where a clock duty cycle is not 50%, a duty-cycle correction circuit may be used to generate a clock signal having a duty-cycle of 50%. The duty-cycle correction circuit corrects duty-cycle errors by reducing an error of the duty-cycle. If the circuit corrects the duty cycle to be 50%, it reduces the error to 0. As such, a circuit can use a corrected internal clock signal even if an external clock signal has a duty-cycle error.

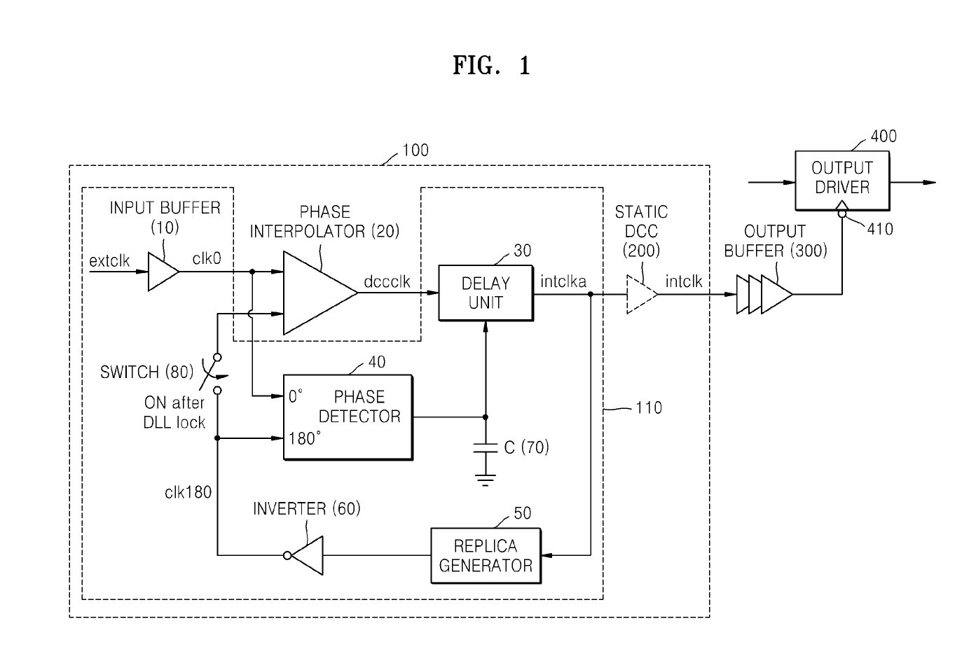

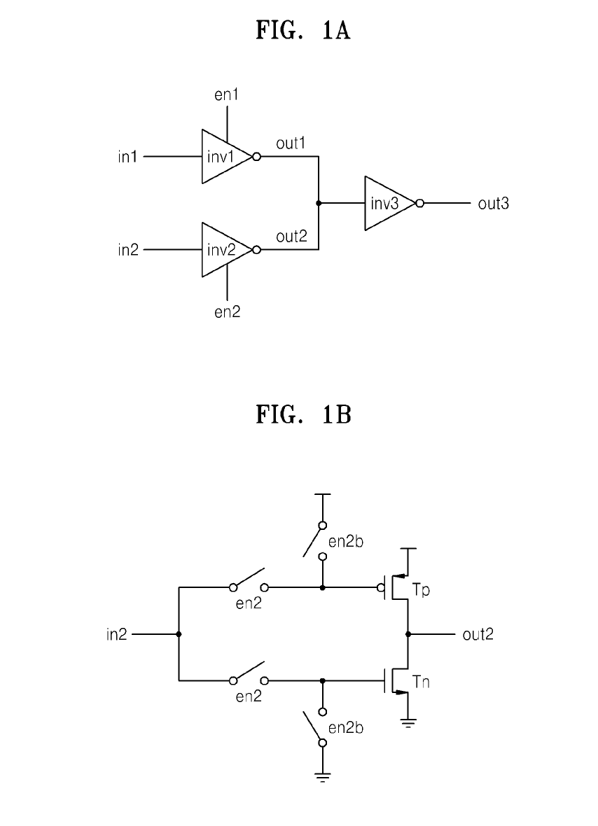

FIG. 1 is a circuit diagram of an exemplary duty-cycle error correction circuit 100 connected to an output buffer 300 and output driver 400, according to one embodiment. The duty-cycle error correction circuit 100 may be used, for example, to generate an internal output signal intclk that has little or no duty cycle error (e.g., a duty cycle at or near 50%). In one embodiment, the internal output signal may be sent through an output buffer to an output driver, at which point it serves as an internal clock signal that is in phase with the external clock signal and that has little or no duty cycle error. As such, the duty-cycle error correction circuit 100 functions as part of an internal clock generation circuit that generates an internal clock for a semiconductor device.

In one embodiment, the duty-cycle error correction circuit 100 includes an inversion and delay circuit 110 (also referred to as a delay locked loop circuit 110), a phase interpolator 20, and a static duty-cycle error correction circuit 200. A description of the elements and functions of these circuits is described below.

The inversion and delay circuit 110 includes an input buffer 10, a delay unit 30, a replica generator 50, an inverter 60, a phase detector 40, a switch 80, and a capacitor 70. In one embodiment, the inversion and delay circuit 110 has dual functions as a delay locked loop circuit that operates to lock the phase of a signal, and an inversion and delay circuit that inverts and delays a signal. Phase interpolator 20 includes circuitry for correcting a duty cycle of input signals, as discussed further below. An example of a phase interpolator is also discussed, for example, by Kao et al., “All-Digital Fast-Locked Synchronous Duty-Cycle Corrector,” published by IEEE in 2006, and incorporated herein by reference in its entirety.

Although switch 80 is depicted as being part of the inversion and delay circuit 110, it may alternatively be considered as part of a dynamic duty cycle error correction circuit that includes phase interpolator 20, delay unit 30, replica generator 50, inverter 60, switch 80, phase interpolator 40, and capacitor 70. The static duty cycle error correction circuit 200 (static DCC 200) includes further circuitry for correcting static duty cycle error in a signal.

As shown in FIG. 1, input buffer 10 is connected to an external clock, phase interpolator 20, and phase detector 40. Phase interpolator 20 is connected at its input to the input buffer 10 and an output of an inverter 60 (when switch 80 is on), which both provide signals as inputs to phase interpolator 20. Phase interpolator is connected at its output to a delay unit 30. Delay unit 30 is connected to phase interpolator 20 to receive a clock signal, phase detector 40 to receive a control signal, and static DCC 200 and replica generator 50 to which it sends signals. Replica generator is connected between delay unit 30 and inverter 60, and inverter 60 further connects at its output to phase detector 40, switch 80, and (when switch 80 is closed) phase interpolator 20. Phase detector 40 is connected to inverter 60 and input buffer 10 to receive signals, and is connected at its output to delay unit 30 and, in one embodiment capacitor 70, which stores the delay signal output from delay unit 30. Static DCC 200 is connected at its input to delay unit 50 and at its output to an output buffer 300, though Static DCC 200 is optional such that the output of delay unit 50 can be connected to output buffer 300 without going through Static DCC 200. Output buffer 300 is further connected at its output to output driver 400 via, in one embodiment, an inverter 410.

In general, an external clock signal (extclk) is initially input to the duty-cycle error correction circuit 100 and switch 80 is initially turned OFF (i.e., disconnected). The inversion and delay circuit 110 then inverts the external clock signal and delays the external clock signal, and over a series of clock cycles, causes the external clock signal and inverted delayed clock signal to be in phase (e.g., by virtue of their rising clock edges). After the inverted delayed clock signal and the external clock signal are in phase, switch 80 turns ON (e.g., connects), and then over a series of one or more clock cycles, the interpolator 20 corrects the duty cycle error by a percentage (e.g., 50%, 66.6%, 100%). Any remaining duty cycle error after the corrections by interpolator 20 can be corrected by a conventional static duty error correction circuit 200. However, in other embodiments, the static duty cycle error correction circuit 200 need not be used. A corrected signal is then output from the duty-cycle error correction circuit 100 as an internal output signal, which can be propagated to an output driver 400 (e.g., through output buffer 300) to be used as an internal clock signal. The duty-cycle error correction circuit 100 will now be described in greater detail.

As discussed above, when the external clock is initially turned on, switch 80 is in the OFF (disconnected) state. The external clock signal extclk, which may have a duty cycle error, is input into inversion and delay circuit 110. The external clock signal extclk then passes through an input buffer 10, which outputs a clock signal clk0. In one embodiment, clk0 has the same frequency and duty cycle as extclk, and the two signals are substantially in phase (e.g., with negligible delay differences). Clk0 is then input into phase interpolator 20. The phase interpolator 20 is configured to accept two input signals and combine them to output a duty cycle error corrected clock signal dccclk. However, because switch 80 is initially OFF, only one signal, clk0, is initially input into phase interpolator 20, and so the same signal, clk0, is output from phase interpolator 20 as dccclk, which is substantially in phase with clk0 (e.g., with negligible delay differences).

An exemplary phase interpolator 20 is depicted in FIGS. 1a and 1b. As shown, in FIG. 1a, interpolator may include two inverters inv1 and inv2, each connected to separate enable lines en1 and en2. The input in1 (clk0 in FIG. 1) is input into the first inverter inv1 and the input in2 (clk180 in FIG. 1) is input into the second inverter inv2. The outputs out1 and out2 of the inverters are tied together such that the phase interpolator 20 combines the inverted signals and then feeds the combined signal into a third inverter inv3, which outputs a signal out3, which is a duty-cycle error corrected signal.

When switch 80 is ON, in1 and in2 are both input into interpolator 20, and the two signals are inverted and used to form interpolated output signal out3. However when switch 80 is OFF, only in1 is used to form interpolated output signal out3, and thus out3 is the same signal as in1. To achieve this, a circuit such as shown in FIG. 1b may be used to comprise inverter inv2. As shown in the circuit, when en2 is in an ON state, the switches labeled en2 are ON, the switches labeled en2b (en2 “bar”, which are in the opposite state of en2), are OFF, and the circuit behaves as an inverter. However, when en2 is OFF, switches labeled en2 are OFF, and switches labeled en2b are ON, such that both transistors Tp and Tn are OFF, and thus the output from the inverter is a high impedance and the signal passing through inverter inv2 is essentially cut off. As a result, only the signal output from inverter inv2 (out1) is input into the inverter inv3, such that in1 (clk0) is the same signal as out3 (dccclk). In one embodiment, the signal en2 controlling inverter inv2 may be tied to a signal controlling switch 80, such that when switch 80 is ON, the switches en2 in inverter inv2 are also ON.

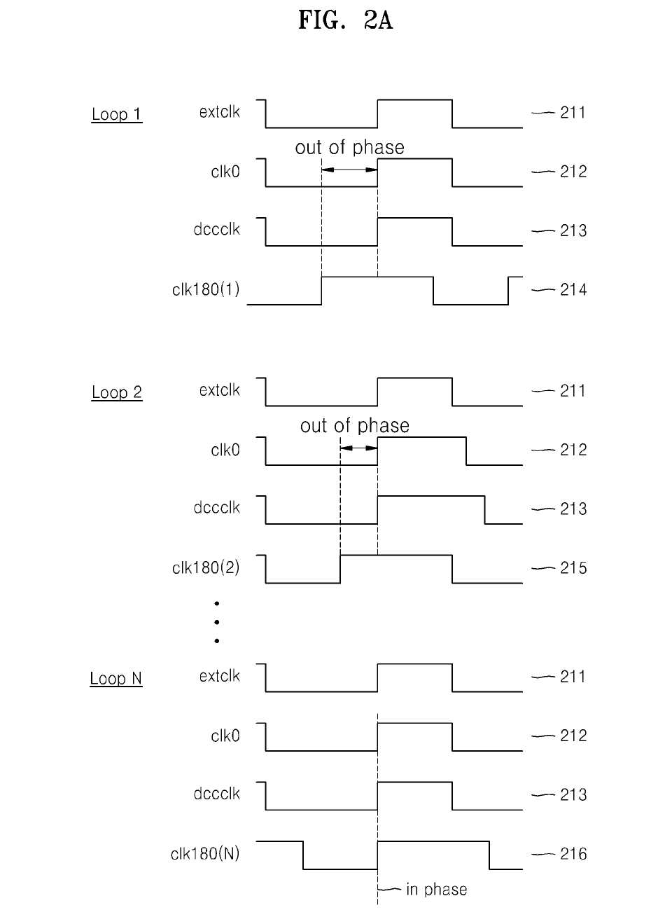

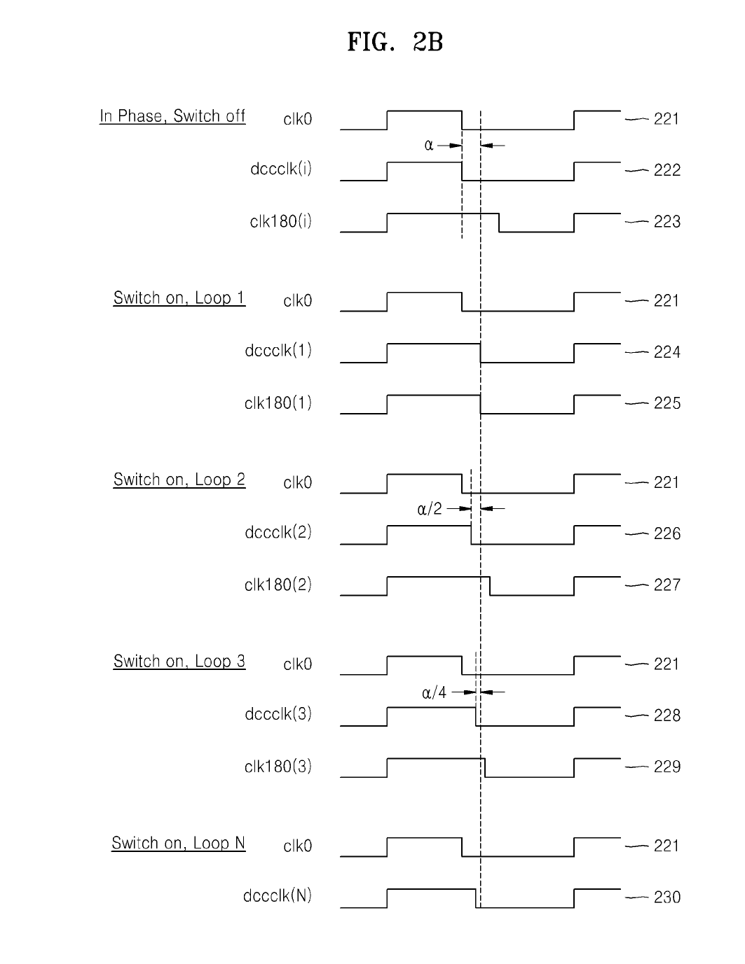

FIG. 2a is an exemplary timing diagram regarding an initial operation duty-cycle error correction circuit 100 when switch 80 is off (disconnected). More specifically, FIG. 2a illustrates the initial timing of signals extclk, clk0, and dccclk, as well as the timing of signal clk180 as its duty cycle changes over various loops of the inversion and delay circuit 110 until it reaches a phase that is locked with the phase of clk0.

Thus, as shown in FIG. 2a, when the external clock signal extclk is initially received, it initially may have a waveform 211 as shown in FIG. 2a as extclk. That is, it has a duty cycle of 40% (i.e., 40% of the clock cycle is in the high voltage state, and 60% is in the low voltage state). The external clock signal extclk is then fed into input buffer 10 which outputs external input signal clk0 in response. As shown in waveform 212, external input signal clk0 has the same phase and duty cycle as extclk. In one embodiment, as depicted in FIG. 2a, the clk0 has no delay, or insignificant delay when compared to extclk. However, in other embodiments, a delay may be associated with input buffer 10 such that the signal clk0 is slightly delayed and thus is slightly out of phase with extclk. In such an embodiment, as discussed further below, the delay unit 30 and/or replica generator 50 can be set to compensate for the difference in phase, such that the clock signal reaching output driver 400 has the same phase as extclk.

External input signal clk0 is then input into both phase interpolator 20 and phase detector 40. Because initially switch 80 is OFF, the circuitry in interpolator 20 causes a signal having the same frequency and duty cycle as clk0 to be output as dccclk from interpolator 20. In one embodiment, as depicted in FIG. 2a as waveform 213, the signal dccclk has no delay, or insignificant delay when compared to clk0. However, in other embodiments, a delay may be associated with interpolator 20 such that the signal dccclk is slightly delayed and thus is slightly out of phase with clk0. In such an embodiment, as discussed further below, the delay unit 30 and/or replica generator 50 can be set to compensate for the difference in phase.

The dccclk signal is then input into delay unit 30, which may be set in one embodiment to initially cause no delay in the signal. The initial output signal intclka from delay unit 30 is then fed into replica generator 50, which replicates the path through which the signal intclka would have to travel to be received at inverter 410, and thus applies delay components that mimic the delay associated with that path (e.g., delay associated with input buffer 10, static DCC 200 (if one is used), and output buffer 300). The delayed signal is then fed into inverter 60. As a result, the output from inverter 60 is an inverted delayed clock signal clk180. An example of the waveform for clk180 in the initial loop of inversion and delay circuit 110, labeled as clk180(1) is shown as waveform 214 in FIG. 2a. As illustrated by waveform 214, the initial clk180(1) signal is an inverted and delayed form of dccclk.

Because switch 80 is OFF, inverted delayed clock signal clk180 is not input into phase interpolator 20, but is only input into phase detector 40. Phase detector 40 then compares external input signal clk0 to inverted delayed clock signal clk180(1) and determines if the rising edges of the signals are in phase. If they are not, as illustrated in comparing waveform 212 (clk0) to waveform 214 (clk180(1)) then phase detector 40 outputs a delay control signal to delay unit 30, instructing delay unit 30 to delay the next incoming dccclk signal a predetermined amount. In one embodiment, the amount of delay instructed by the control signal is a small incremental amount.

During the next loop of inversion and delay circuit 110, the signals extclk, clk0, and dccclk have the same phase and duty cycle as during the first loop of the circuit, but the delay unit 30 causes the dccclk signal to be additionally delayed and outputs the delayed signal as intclka. This delayed signal is fed into replica generator 50, and inverter 60, and is output from inverter 60 as clk180(2), depicted as waveform 215 in FIG. 2a. The clk180(2) signal is then compared to clk0 by phase detector 40, and if the rising edges are not in phase, phase detector 40 outputs another control signal to delay unit 30 instructing delay unit 30 to delay the incoming signals an additional predetermined amount. This loop continues until the phase detector 40 determines that the external input signal clk0 and the inverted delayed clock signal clk180 have rising edges that are in phase. When that occurs, as depicted by waveform 216 (clk180(N)), the inversion and delay circuit 110 is locked, and the two signals clk0 and clk180 are in phase, but have opposite duty cycles.

In one embodiment, after the signals clk180 and clk0 are in phase and the inversion and delay circuit 110 is locked, switch 80 is switched to ON (e.g., connected) such that the inverted delayed clock signal clk180 is fed into phase interpolator 20. For example, the switch may be connected to a circuit that includes a counter to count the number of clock cycles, wherein after a predetermined number of clock cycles (e.g., 100, 200), the inversion and delay circuit 110 can be assumed to be locked. Alternatively, switch 80 could be switched based on the control signals output from phase detector 40, or based on other criteria related to the locking of the inversion and delay circuit 110.

After switch 80 is switched ON, phase interpolator 20 begins to function as part of a dynamic duty cycle error correction circuit. That is, the dynamic duty cycle error correction circuit interpolates the duty cycles of clk0 and clk180 to produce an output that is corrected for duty cycle error, shown as duty cycle error corrected clock signal dccclk. After a number of clock cycles and loops of the circuit comprising input buffer 10, phase interpolator 20, delay unit 30, replica generator 50, and inverter 60, the duty cycle error corrected clock signal dccclk converges to a stable state or level, that is closer to 50% than the initial external input signal clk0. An example of the convergence to a stable level is shown in FIG. 2b.

FIG. 2b is an operational timing view of the duty-cycle error correction circuit of FIG. 1. FIG. 2b illustrates principles of duty-cycle error correction by using the phase interpolator 20. In the embodiment shown in FIG. 2b, initially, the external input signal clk0 having a duty-cycle error (−α%) (clk0, depicted as waveform 221) and the inverted delayed clock signal clk180 having a duty cycle error (+α%) (clk180(i), depicted as waveform 223) are aligned (e.g., a locked status of the inversion and delay circuit 110 as described above). In addition, just prior to the switch 80 being turned ON, the signal dccclk(i) (waveform 222) output from phase interpolator 20 has the same phase and duty cycle error as clk180(i), though in one embodiment, it may be delayed slightly due to the circuitry in phase interpolator 20 and be slightly out of phase. The phase interpolator 20 then interpolates the clk0 and clk180 signals to generate a duty-cycle error corrected clock signal dccclk(1), depicted as waveform 224, having a corrected duty-cycle error.

However, because the duty-cycle corrected clock signal dccclk(T1) continues through the loop including phase interpolator 20, delay unit 30, replica generator 50, and inverter 60, the signal dccclk(1) is inverted again (waveform 225, clk180(1)) while circulating the inversion and delay circuit 110 and then is interpolated with the external input signal clk0, and a recursive offset is generated.

For example, when the duty-cycle error value α is 10%, the external input signal clk0 has a duty cycle of 40% (e.g., high voltage state for 40% of the cycle) and the inverse-locked inverted delayed clock signal clk180 initially has a duty cycle of 60%. Furthermore, as a result of these duty-cycle error values, the duty-cycle error corrected clock signal dccclk(1), which is corrected by the phase interpolator 20, has a duty cycle of 50%. For example, in one embodiment, phase interpolator 20 may be configured to compare the duty cycles of the two input signals and take an average of the two to produce a resulting signal having a duty cycle between the two inputted signals (e.g., if one input has 60% duty cycle and the other has 40% duty cycle, the resulting signal can have a 50% duty cycle). In the next loop of the circuit, the resulting duty-cycle error corrected clock signal dccclk(1) is inverted (clk180(1)) while circulating along the inversion delay loop of phase interpolator 20, delay unit 30, replica generator 50, and inverter 60, and the inversed signal (having 50% duty cycle) is interpolated with the input clock signal clk0 (having 40% duty cycle) again to generate a duty-cycle error corrected clock signal dccclk(2) (waveform 226).

The resulting signal dccclk(2) has a duty cycle of 45% (e.g., halfway between the clk0 duty cycle of 40% and the dccclk(1) duty cycle of 50%), and when that signal dccclk(2) is inverted (clk180(2), waveform 227) while passing through inverter 60, the inverted duty-cycle error correction clock signal dccclk(180)(2), has a duty of 55%. This signal is then interpolated with the external input signal clk0 (having duty cycle of 40%) again, resulting in a corrected duty-cycle error correction clock signal dccclk(3), depicted as waveform 228 (having a duty cycle of 47.5%). The corrected duty cycle error corrected clock signal dccclk(T) is inverted again (to have a duty cycle of 52.5%, as shown in waveform 229, clk180(3)), and is then interpolated with the external input signal clk0.

When the above described loop is circulated N times, an inverted duty-cycle error corrected clock signal dccclk(180)(N−1) and the input clock signal clk0 are interpolated to generate a stable duty-cycle error corrected clock signal dccclk(N), depicted as waveform 230.

<Table 1> below shows changes in the high level duty cycle value of the duty cycle error corrected clock signal dccclk, when the initial duty cycle is 40%, such as in the exemplary case above, where the above described loop is circulated repeatedly.

TABLE 1

| Number of times | Duty-cycle error | |
|---|---|---|
| the loop is | corrected clock | |
| circulated | signal | Duty cycle value |
| 0 | clk0(i) | 0.400000 |
| 1 | dccclk(1) | 0.500000 |
| 2 | dccclk(2) | 0.450000 |
| 3 | dccclk(3) | 0.475000 |
| 4 | dccclk(4) | 0.462500 |
| 5 | dccclk(5) | 0.468750 |
| 6 | dccclk(6) | 0.465625 |
| 7 | dccclk(7) | 0.467188 |
| 8 | dccclk(8) | 0.466406 |
| 9 | dccclk(9) | 0.466797 |
| 10 | dccclk(10) | 0.466602 |
| 11 | dccclk(11) | 0.466699 |
| 12 | dccclk(12) | 0.466650 |
| 13 | dccclk(13) | 0.466675 |
| 14 | dccclk(14) | 0.466663 |
| 15 | dccclk(15) | 0.466669 |
| 16 | dccclk(16) | 0.466666 |

Thus, in this example where the duty cycle of clk0 is 60%, when the above loop is circulated repeatedly, the duty cycle of the internal clock signal intclka converges to a stable value of 46.666%.

That is, when the duty-cycle error value α in the external input signal clk0 is 10%, the error value is corrected to 3.333%. Therefore, 66.6% of the initial duty-cycle error may be corrected, and 33.3% of the initial duty-cycle error remains. In this example, the duty-cycle error correction circuit 100 modifies a Y % duty cycle of the input clock clk0 to approach or equal about X %, where X %=(100%+Y %)/3.

In the embodiment depicted in FIGS. 2a and 2b, because 33.3% of the initial 10% offset remains, the duty-cycle error correction is not corrected entirely. However, a majority (e.g., 66.6%) of the duty-cycle error may be corrected at the input terminal via phase interpolator 20, which results in a dynamic duty correction effect that corrects in real-time the duty-cycle error included in the external input signal clk0. In one embodiment, the time for reaching the final duty correction value may be related to the loop bandwidth of the inversion and delay circuit 110.

Referring to FIG. 1 again, the duty-cycle error corrected clock signal dccclk(Tn) generated by circulating the loop N times passes through the delay unit 30, and is output as an initial internal output signal intclka. Although not shown, a switch, similar to switch 80, may be used at the output of delay unit 30. Thus, in one embodiment, the switch would turn ON after the duty-cycle error of the signal passing through interpolator reaches a stable state, thus allowing the signal to pass through to output driver 400.

In one embodiment, a conventional static DCC 200 may be disposed to receive the intclka signal from delay unit 30, and may correct any remaining duty-cycle error of the initial internal output signal intclka and output an internal output signal intclk. The internal output signal intclk may then be output to the output driver 400 via the output buffer 300, such that the signal reaching output driver 400 is in phase with the external clock signal extclk, but has duty-cycle errors removed.

According to the above embodiments, because the duty-cycle error is reduced at an initial stage of the correction process, the static DCC 200 need not correct the entire duty cycle, and so the correcting range of the static DCC 200 may be reduced. That is, when the input duty-cycle error is 10%, the static DCC 200 corrects only 3.333% out of the 10% duty-cycle error, while the remaining 6.666% of the error is corrected via the interpolator 20. Therefore, the correction range of the duty-cycle error for the static DCC 200 may be reduced, and thus, power consumption may be reduced. In one embodiment, static DCC 200 can be a conventional static duty cycle error correction circuit. Therefore, detailed descriptions of the static DCC 200 are not provided.

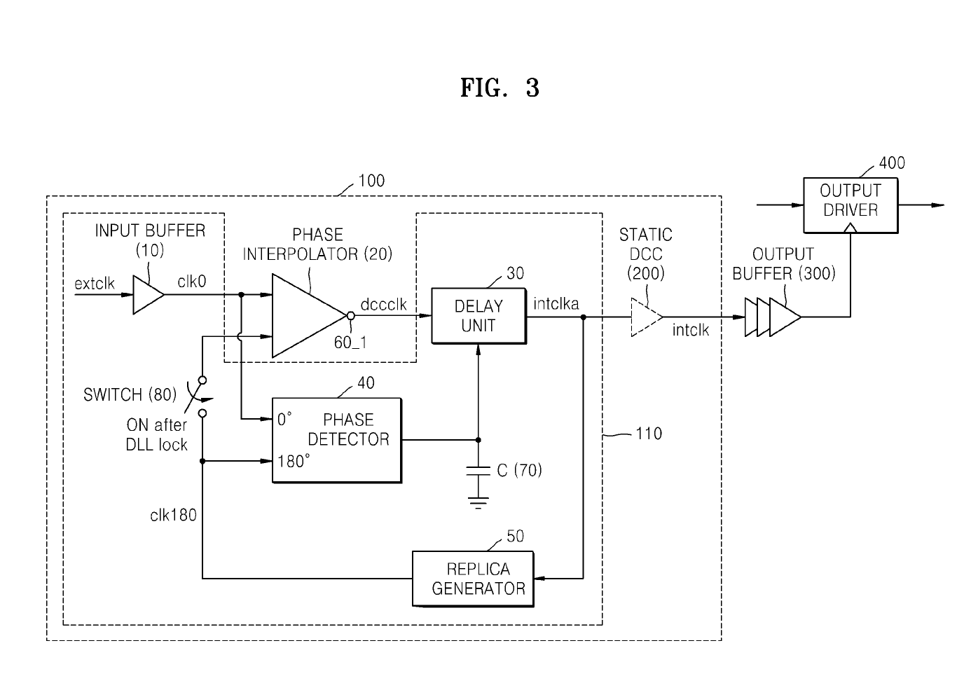

FIG. 3 is an exemplary circuit diagram of a duty-cycle error correction circuit according to another embodiment.

Referring to FIG. 3, an inverter 60_1 is located at an output end of the phase interpolator 20.

Unlike the embodiment depicted in FIG. 1, the duty-cycle error correction circuit 100 of FIG. 3 inverts the signal coming out of the phase interpolator 20 prior to the signal reaching the delay unit 30 and the replica generator 50. Accordingly, inversion of the signal output from the replica generator 50 and inversion of the signal at the output driver 400 may be removed. Therefore, in the embodiment shown in FIG. 3, inverters 60 and 410 of FIG. 1 are not used, but are replaced by an inverter 60_1 placed at the output of phase interpolator 20.

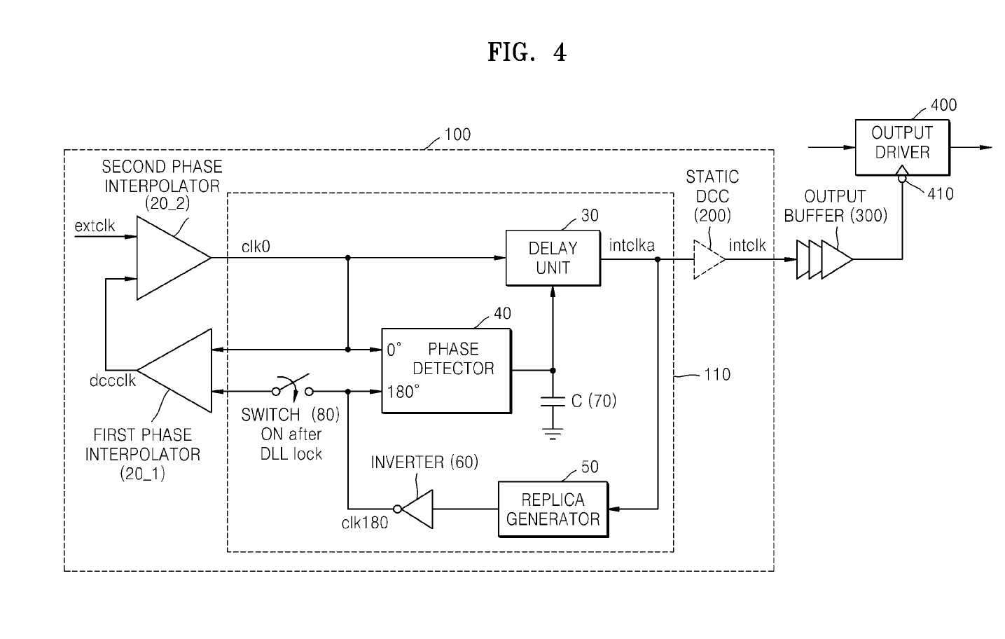

FIG. 4 is an exemplary circuit diagram of a duty-cycle error correction circuit according to yet another embodiment.

Referring to FIG. 4, the external clock signal extclk passes through duty-cycle error correction circuit 100, and then, a duty-cycle error corrected clock signal obtained by correcting the duty-cycle error of the external signal extclk is output as an internal output signal intclk. The initial internal output signal intclka is input to the static DCC 200 so that the duty-cycle error of the initial internal output signal intclka is corrected, input into static DCC 200, and then is output from static DCC 200 as an internal output signal intclk to the output driver 400 via the output buffer 300 and inverter 410. The signal received at the output driver 400 is a duty-cycle corrected signal that is in phase with extclk.

The duty-cycle error correction circuit 100 according to the embodiment of FIG. 4 includes an inversion and delay circuit 110, a first phase interpolator 20_1, a second phase interpolator 20_2, and a static duty cycle error correction circuit 200.

The inversion and delay circuit 110 includes the delay unit 30, the replica generator 50, the inverter 60, the phase detector 40, the capacitor 70 and the switch 80. Inversion and delay circuit 110 causes a clock signal to have its phase locked, and also causes an inversion delay signal. The elements of inversion and delay circuit 110 may be the same as those described above with reference to FIG. 1, and thus, detailed descriptions of the above components are not provided. Hereinafter, the first and second phase interpolators 20_1 and 20_2 will be described as follows.

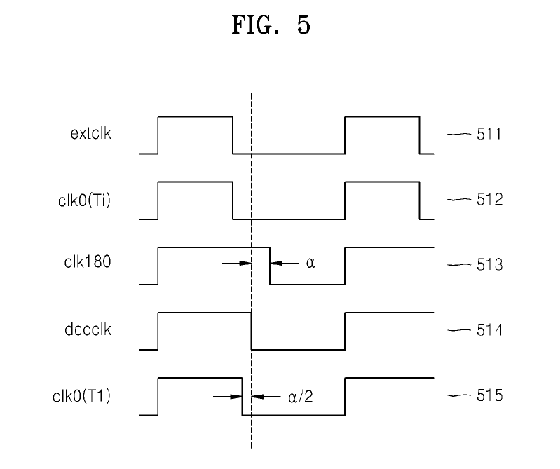

The first phase interpolator 20_1 is located at an input terminal of the inversion and delay circuit 110 to receive the external input signal clk0 and the inverted delayed signal clk180 (waveform 513 in FIG. 5), and generates the first duty-cycle error corrected clock signal dccclk (waveform 514) by interpolating the initial external input signal clk0(i) (waveform 512) and the inverted delayed clock signal clk180.

The second phase interpolator 20_2 is located at an input terminal of the inversion and delay circuit 110 to receive the external clock signal extclk (waveform 511) and the first duty-cycle error corrected clock signal dccclk, and generates the second duty-cycle error corrected clock signal clk0(1) (waveform 515) by interpolating the external clock signal extclk and the first duty-cycle error corrected clock signal dccclk.

FIG. 5 is an exemplary operational timing diagram of the duty-cycle error correction circuit of FIG. 4.

Initially, the first duty-cycle error corrected clock signal dccclk (waveform 514) output from the first phase interpolator 20_1 has no duty-cycle error. That is, the high level duty and the low level duty are equal to each other (i.e., 50%). The first duty-cycle error corrected clock signal dccclk is then input into the second phase interpolator 20_2 to be interpolated with the external signal extclk to generate the second duty-cycle error corrected clock signal clk0(1) (waveform 515). The second duty-cycle error corrected clock signal clk0(1) reduces the duty-cycle error from the external clock signal extclk by 50%. That is, as shown in FIG. 5, if the duty-cycle error in the external signal extclk is α, the duty-cycle error in the second duty-cycle error correction signal clk0(T) is reduced to α/2. As such, in the circuit of FIG. 4, the steady state duty cycle error corrected clock signal is reached after one loop of the duty-cycle error correction circuit 100 and is reduced by 50% compared to the duty cycle of the external clock signal.

Referring back to FIG. 4, the second duty-cycle error corrected clock signal clk0(1) passes through the delay unit 30 and is output as the initial internal output signal intclka. As described above, a static DCC 200 may be used to correct the remaining duty cycle error. A switch may also be used. An internal output signal intclk that has no duty cycle error is then output to the output driver 400 via the output buffer 300.

According to the embodiment depicted in FIGS. 4 and 5, if the external input signal duty-cycle error is 10%, then 50% of the error is corrected by the interpolators 20_1 and 20_2, and the static DCC 200 located at the rear portion in the duty-cycle error correction circuit 100 corrects the other 50% (e.g., only 5% of duty-cycle error) which remains after the correction by the interpolators. Therefore, the correction range of the duty-cycle error for the DCC 200 may be reduced, and thus, power consumption required to achieve a stable duty corrected signal state may be reduced.

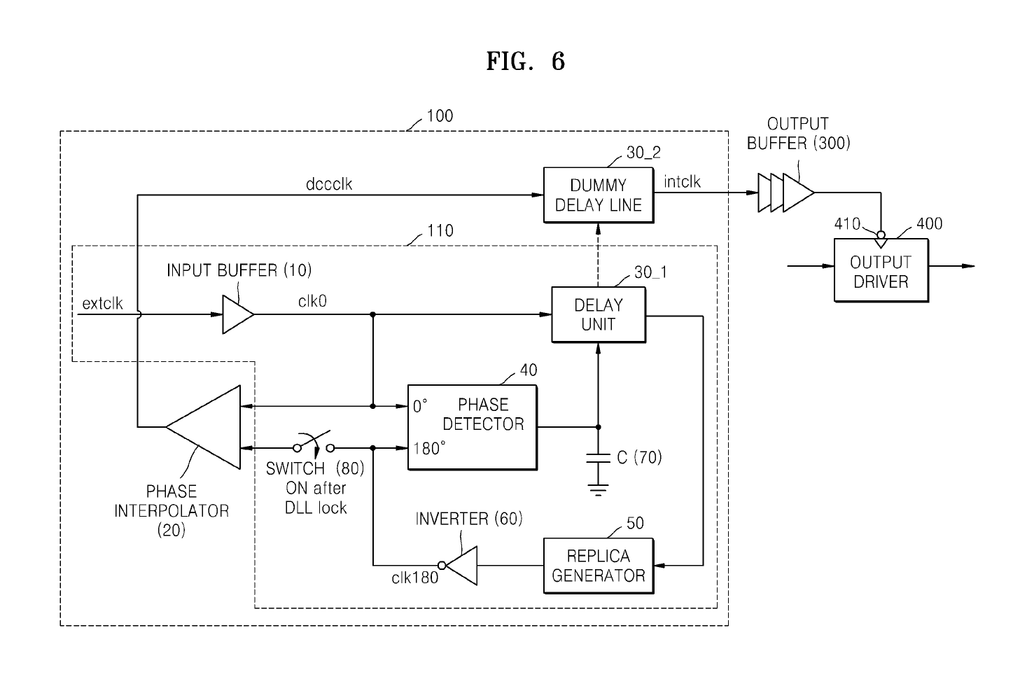

FIG. 6 is an exemplary circuit diagram of a duty-cycle error correction circuit according to another embodiment.

The duty-cycle error correction circuit 100 of FIG. 6 has a similar structure to that of FIG. 1, however, output from the phase interpolator 20, dccclk, is output directly as an internal output signal intclk via a dummy delay line 30_2, unlike the duty-cycle error correction circuit 100 of FIG. 1, in which the output from the phase interpolator 20 is input into the delay unit 30 and circulates repeatedly the loop of the inversion and delay circuit 110. In addition, the duty-cycle error correction circuit 100 of FIG. 6 does not include an additional static DLL.

Referring to FIG. 6, the external clock signal extclk passes through the duty-cycle error correction circuit 100, and the duty-cycle error corrected clock signal dccclk is output as the internal output signal intclk. The internal output signal intclk is output to the output driver 400 via the output buffer 300, such that an internal clock signal at the output driver 400 is in phase with the extclk signal, but with duty-cycle errors corrected.

The duty-cycle error correction circuit 100 according to the embodiment shown in FIG. 6 includes the inversion and delay circuit 110, the phase interpolator 20, and the dummy delay line 30_2.

The inversion and delay circuit 110 includes a delay unit 30_1, the replica generator 50, the inverter 60, the phase detector 40, capacitor 70, switch 80, and input buffer 10. Detailed descriptions of the above components are not provided here. The phase interpolator 20 and the dummy delay line 30_2 are described below.

The phase interpolator 20 is located at the input end of the inversion and delay circuit 110 to receive the external input signal clk0 and the inverted delayed signal clk180, and generates the duty-cycle error corrected clock signal dccclk, in which the duty-cycle error of the external input signal clk0 is corrected up to 100%, by interpolating the external input signal clk0 and the inverted delayed signal clk180.

The duty-cycle error corrected clock signal dccclk is input to the dummy delay line 30_2, and output as the internal output signal intclk.

In one embodiment, the delay amount of the dummy delay line 30_2 is the same as the amount controlled by a control signal generated from the phase detector 40, and the dummy delay line 30_2 has the same structure as that of the delay unit 30_1 in the loop.

According to the duty-cycle error correction circuit 100 of FIG. 6, similarly to the embodiment of FIG. 1, the inversion and delay circuit 110 first achieves locking such that the rising edges of the clock cycles of clk0 and clk180 are in phase. Next, the external input signal clk0 is interpolated with the inverted delayed clock signal clk180 by phase interpolator 20 to correct the duty-cycle error. As a result, the duty cycle is corrected 100% (i.e., if clk0 had a duty cycle of 40% and clk180 had a duty cycle of 60%, phase interpolator 20 corrects the signals so they average to a 50% duty cycle). The corrected signal, dccclk, is sent through dummy delay line 30_2, and is output as the internal output signal intclk. The signal intclk is then sent through output buffer 300 to output driver 400 to be used as the internal clock signal, which in one embodiment is phase with the external clock signal extclk, and has duty-cycle errors corrected.

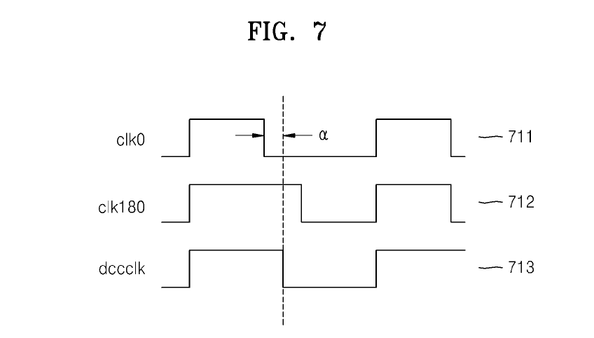

FIG. 7 is an exemplary operational timing diagram of the duty-cycle error correction circuit 100 of FIG. 6.

The duty-cycle error corrected clock signal dccclk output from the phase interpolator 20 has no duty-cycle error. That is, the high level duty and the low level duty are equal to each other. As shown in FIG. 7, when the duty-cycle error in the external input signal clk0 (waveform 711) is α, the duty-cycle error in the duty-cycle error corrected clock signal dccclk (waveform 713) is 0.

According to the duty-cycle error correction circuit 100 of the embodiment of FIGS. 6 and 7, the duty cycle error of the external input signal clk0 is completely corrected, and there is no need to dispose the DCC 200 at the rear portion of the duty-cycle error correction circuit 100. In addition, the duty-cycle error correction circuit 100 has a simple structure because it does not include an additional phase detector or static DCC when compared with the dual-loop DCC circuit. Also, the duty-cycle error may be corrected in real-time.

While various exemplary embodiments have been particularly shown and described above, it will be understood that various changes in form and details may be made therein without departing from the spirit and scope of the following claims.

What is claimed is:

1. A duty cycle error correction circuit comprising:
an inversion and delay circuit configured to:
receive an input signal having a waveform that includes a duty cycle error,
delay and invert the input signal to form an inverted delayed signal, and
determine whether the input signal and the inverted delayed signal are in phase; and
a phase interpolator configured to:
receive the input signal,
receive the inverted delayed signal,
interpolate the received input signal and the received inverted delayed signal, and
based on the interpolation, output a duty cycle error corrected signal.

2. The duty cycle error correction circuit of claim 1, wherein the inversion and delay circuit is configured to output the duty cycle error corrected signal as an internal output signal after a duty-cycle error of the input signal is corrected.

3. The duty cycle error correction circuit of claim 1, wherein:
the input signal has a duty cycle error of a certain percent; and
the duty cycle error corrected signal has a duty cycle error between half of the certain percent and zero.

4. The duty-cycle error correction circuit of claim 1, further comprising an additional duty-cycle correction circuit configured to receive the duty cycle error corrected signal, and to correct any remaining duty cycle error not corrected by the phase interpolator.

5. The duty-cycle error correction circuit of claim 1, wherein the inversion and delay circuit comprises:
a delay unit delaying the duty-cycle error corrected signal;
a replica generator matching phases of the input signal and a signal driving an output driver;
an inverter inverting the phase of the signal output from the replica generator; and
a phase detector that receives the external input signal and the inverted delayed signal to determine whether the input signal and the inverted delayed signal are in phase.

6. The duty-cycle error correction circuit of claim 1, wherein an inverter is located at an output end of the phase interpolator and inverts a phase of a signal output from the phase interpolator.

7. The duty-cycle error correction circuit of claim 1, wherein the phase interpolator is part of a loop such that the phase interpolator recursively interpolates the input signal and an inverted delayed signal until the output from the phase interpolator reaches a stable state.

8. The duty-cycle error correction circuit of claim 1, further comprising:
a phase detector that is part of the inversion and delay circuit and that determines whether the input signal and the inverted delayed signal are in phase; and
a switch configured to change to an ON state when the phase detector determines that the input signal and the inverted delayed signal are in phase.

9. The duty-cycle error correction circuit of claim 1, further comprising:
a dummy delay line configured to receive the duty-cycle error corrected signal and generate an internal output signal.

10. The duty-cycle error correction circuit of claim 9, wherein the inversion and delay circuit comprises:
a delay unit delaying the external input signal;
a replica generator matching phases of the external input signal and a signal driving an output driver to generate a replica signal;
an inverter inverting the phase of the replica signal; and
a phase detector detecting a phase difference between the external input signal and the inverted delayed signal.

11. A duty-cycle error correction circuit comprising:
a first phase interpolator generating a first duty-cycle error corrected signal by interpolating an external input signal and an inverted delayed signal;
an inversion and delay circuit generating the inverted delayed signal by delaying and inverting the external input signal, and when the inverted delayed signal and the external input signal are in phase, transmitting the inverted delayed signal to the first phase interpolator; and
a second phase interpolator generating a second duty-cycle error corrected signal by interpolating the external input signal and the first duty-cycle error corrected signal.

12. The duty-cycle error correction circuit of claim 11, wherein the inversion and delay circuit outputs the second duty-cycle error corrected signal as an internal output signal.

13. The duty-cycle error correction circuit of claim 12, further comprising a static duty-cycle correction circuit which receives the internal output signal and corrects a duty-cycle error of the internal output signal.

14. The duty-cycle error correction circuit of claim 11, wherein the inversion and delay circuit comprises:
a delay unit delaying the external input signal;
a replica generator matching phases of the external input signal and a signal driving an output driver to generate a replicated signal;
an inverter inverting the phase of the replicated signal to create the inverted delayed signal; and
a phase detector detecting a phase difference between the external input signal and the inverted delayed signal.

15. A method of correcting a duty-cycle error in a clock signal, the method including:
(a) inverting and delaying an external input signal received from an external clock, thereby creating an inverted delayed signal;
(b) determining whether the inverted delayed signal is in phase with the external input signal;
(c) if the inverted delayed signal is not in phase with the external input signal, then repeating steps (a) and (b) with a successively increased amount of delay until it is determined that the inverted delayed signal is in phase with the external input signal;
(d) after it is determined that the inverted delayed signal is in phase with the external input signal, inputting the inverted delayed signal into an interpolator; and
(e) interpolating by the interpolator the inverted delayed signal and the external input signal, and outputting a first output signal that has a reduced duty-cycle error compared to the external input signal.

16. The method of claim 15, further comprising:
(f) delaying and inverting the first output signal;
(g) feeding the delayed and inverted first output signal into the phase interpolator;
(h) interpolating by the interpolator the delayed and inverted first output signal and the external input signal, and outputting a second output signal that has a reduced duty-cycle error compared to the first output signal; and
(i) repeating steps (f) through (h) for subsequent output signals until the output signal reaches a steady state, thereby outputting a final output signal.

17. The method of claim 16, further comprising:
(j) feeding the final output signal into a delay unit; and
(k) outputting a delayed final output signal from the delay unit, and inputting the delayed final output signal to a static duty-cycle error correction circuit, wherein
the static duty-cycle error correction circuit corrects any remaining duty-cycle error, such that a signal output from the static duty-cycle error correction circuit has no duty cycle error.

18. The method of claim 15, wherein the step of inverting and delaying the external input signal received from an external clock includes:
inputting the external input signal into a delay unit, and outputting a delayed signal;
inputting the delayed signal into a replica generator circuit, and outputting a replica signal; and
inputting the replica signal into an inverter.

19. The method of claim 15, wherein the step of inverting and delaying the external input signal received from an external clock includes:
inverting the external input signal;
inputting the inverted external input signal into a delay unit, and outputting a delayed signal; and
inputting the delayed signal into a replica generator circuit.

20. The method of claim 15, further comprising:
performing step (d) in response to turning a switch ON.
